(19) United States
(12) Patent Application Publication
(10) Pub. No.: US 2020/0321477 A1
(43) Pub. Date: Oct. 8, 2020

(54) MULTI-SCHOTTKY-LAYER TRENCH JUNCTION BARRIER SCHOTTKY DIODE AND MANUFACTURING METHOD THEREOF

(71) Applicants: NA REN, LOS ANGELES, CA (US); ZHENG ZUO, LOS ANGELES, CA (US); RUIGANG LI, LOS ANGELES, CA (US)

(72) Inventors: NA REN, LOS ANGELES, CA (US); ZHENG ZUO, LOS ANGELES, CA (US); RUIGANG LI, LOS ANGELES, CA (US)

(73) Assignee: AZ Power, Inc, CULVER CITY, CA (US)

(21) Appl. No.: 16/525,956

(22) Filed: Jul. 30, 2019

Related U.S. Application Data
(60) Provisional application No. 62/829,404, filed on Apr. 4, 2019.

(51) Int. Cl. H01L 29/872; H01L 29/16; H01L 29/47; H01L 29/66; H01L 21/265; H01L 21/285; H01L 21/3213

(52) U.S. Cl. CPC H01L 29/872; H01L 29/1608; H01L 29/47; H01L 21/32139; H01L 21/26513; H01L 21/28537; H01L 29/66143

(57) ABSTRACT

A Schottky diode may include a substrate; an epitaxial layer deposited on top of the substrate; one or more trenches formed on top of the epitaxial layer; an implantation region at a bottom portion of each trench; an ohmic contact metal on the other side of the substrate; a first Schottky contact metal deposited onto the implantation region in each trench to form a first Schottky junction between the first Schottky contact metal and the epitaxial layer at a lower trench sidewall; a second Schottky contact metal filling each trench and extending a predetermined length to each corner of mesas on the epitaxial layer to form a second Schottky junction between the second Schottky contact metal and the epitaxial layer at an upper trench sidewall; and a third Schottky contact metal covering the second Schottky contact metal and the epitaxial layer to form a third Schottky junction.

### CROSS-REFERENCE TO RELATED APPLICATIONS

This application claims priority under 35 U.S.C. § 119 (e) to U.S. Provisional Patent Application Ser. No. 62/829,404, filed on Apr. 4, 2019, the entire contents of which are hereby incorporated by reference.

### FIELD OF THE INVENTION

The present invention relates to a trench type junction barrier Schottky diode, and more particularly to a trench junction barrier Schottky diode with multiple Schottky layers and the manufacturing method thereof.

### BACKGROUND OF THE INVENTION

Silicon carbide (SiC) diodes have been widely approved for their significant advantages in power applications, especially under high voltage/temperature conditions. In general, SiC Schottky diodes are of interest because of low onset voltage (as compared with that of SiC PN junction diodes) and no reverse recovery. However, reverse leakage current of a pure Schottky diode can be significantly larger under high blocking voltage, caused by image force lowering and tunneling effects at the Schottky interface.

Junction Barrier Schottky (JBS) diode structure was proposed to address this problem, which combines the advantages of Schottky junction and PN junction diodes. In JBS structure, plurality of P regions is disposed between Schottky regions. The depletion layer diffuses from PN junction to exhibit pinch-off below the Schottky contact in reverse blocking mode, which can provide electric field shielding effect. As a result, the electric field strength at the Schottky interface can be reduced and the diode leakage current can be decreased subsequently. The electric field shielding effect can be enhanced by increasing the PN junction depth. However, due to the strong lattice of SiC material, the ion implantation depth is only at most 0.8 μm at an implantation energy as high as 380 keV. Trench structure was introduced to increase the PN junction depth by implanting ions into the bottom and sidewalls of trenches. which is shown in FIG. 3. In this structure, the sidewalls of trenches are designed as P-type region. Since the PN junction has no contribution to the forward conduction due to the wide band-gap of SiC material, the channel resistance between adjacent P-type regions could be high, which is bad for the device forward performance.

To reduce the channel resistance, the PN junction formed by the P-type regions in the sidewalls of the trenches can be replaced with N-type Schottky contact, which can be simply formed by a Schottky metal covering the sidewalls of the trenches. As a simple instance, one single metal layer design for both trench sidewall and mesa surface, the option of low barrier Schottky metal will benefit the forward conduction performance while the reverse leakage current could be high due to a high electric field concentration in the center of the mesa. On the other hand, the option of high barrier Schottky metal can suppress the reverse leakage current, but the forward performance benefit could be limited.

A structure with dual metal layers has been developed, namely a low barrier Schottky metal for Schottky junction on the trench sidewall, and a high barrier Schottky metal for Schottky junction on the mesa surface. This dual metal layer structure is believed to have lower forward voltage drop and lower reverse leakage current than one single meal layer structure.

To further improve the forward performance and explore the performance limits of the device, the present invention introduces multiple Schottky layers for the trench structure to enhance electric field distribution. This invention is advantageous for providing low barrier Schottky junction to improve the forward conducting current density and high barrier Schottky junction to suppress the leakage current at high electric field regions. Furthermore, the present invention can achieve a better trade-off between the forward voltage drop and reverse leakage current performances than conventional Schottky diodes.

### SUMMARY OF THE INVENTION

It is an object of the present invention to provide a trench structure with multiple Schottky layers to enhance electric field distribution.

It is another object of the present invention to provide a trench structure with multiple Schottky layers with a low barrier Schottky junction to improve the forward conducting current density, and a high barrier Schottky junction to suppress the leakage current at high electric field regions.

It is a further object of the present invention to provide a trench structure with multiple Schottky layers to achieve a better trade-off between the forward voltage drop and reverse leakage current performances.

In one aspect, a silicon carbide (SiC) multi-Schottky-layer trench junction barrier Schottky diode may include a substrate, an epitaxial layer, a plurality of trenches, a P-type implantation region, an ohmic contact metal, a first Schottky contact metal, a second Schottky contact metal, and a third Schottky contact metal.

In one embodiment, the material selected for the ohmic contact metal can be nickel, silver or platinum. The substrate can be formed by N⁺ type SiC and is located on top of the ohmic contact metal. In another embodiment, the epitaxial layer produced from N⁻ type SiC is located on top of the substrate, and the epitaxial layer can further be patterned and etched with a mask layer to form the trenches. In one embodiment, the depth of each trench is about 1 to 50000 angstrom. The P-type implantation region can be generated at a bottom portion of each trench by ion implantation, and the P-type material may include boron or aluminum, for instance. In one embodiment, the thickness of the P-type implantation region is about 1 to 10000 angstrom.

In an exemplary embodiment, the first Schottky contact metal is deposited on the P-type implantation region in each trench, and a Schottky junction can be formed between the Schottky contact metal and the epitaxial layer at the lower trench sidewall. The second Schottky contact metal is filled into each trench and located on top of the first Schottky contact metal. A Schottky junction can be formed between the second Schottky contact metal and the epitaxial layer at an upper trench sidewall.

It is noted that the Schottky contact metal extends to each corner of the mesas of the epitaxial layer with a predetermined length. A Schottky junction can also be formed between the second Schottky contact meal and the epitaxial layer at each corner of the mesas.

In a further embodiment, the third Schottky contact metal is deposited to cover the second Schottky contact metal and the mesas that are not covered by the second Schottky contact metal. A Schottky junction can then be formed between the third Schottky contact metal and the epitaxial layer at a center portion of each mesa.

In another aspect, a method for manufacturing a silicon carbide (SiC) multi-Schottky-layer trench junction barrier Schottky diode may include steps of: providing a substrate, forming an epitaxial layer on top of the substrate, forming one or more trenches on the epitaxial layer, generating an implantation region at a bottom portion of each trench, providing an ohmic contact metal on an opposite of the substrate, depositing a first Schottky contact metal on top of the implantation region in each trench, forming a second Schottky contact metal on the top of the Schottky contact metal with an extension onto each corner of one or more mesas of the epitaxial layer, and forming a third Schottky contact metal on top of the second Schottky contact metal and the mesas not covered by the second Schottky contact metal.

In one embodiment, the step of providing the substrate includes using N⁺ type SiC as a substrate, and the step of forming the epitaxial layer may include forming an epitaxial layer made from N⁻ type SiC on top of the substrate. The step of forming one or more trenches includes the step of patterning, etching and removing a portion of the epitaxial layer with a mask layer to form the trenches. The step of forming the implantation region may include the step of doping P-type impurity with the mask layer into the bottom of the trench openings.

In another embodiment, the step of providing an ohmic contact metal includes the step of providing an ohmic contact metal underneath the substrate, and a Schottky junction can formed by depositing the first Schottky contact metal on the implantation region in each trench. The step of forming a first Schottky contact metal may further include steps of depositing a metal layer on top of the epitaxial layer and the implantation region in each trench, forming a sacrificial layer to fill each trench, removing the metal layer on the epitaxial layer, and removing the sacrificial layer in each trench. It is noted that a Schottky junction between the first Schottky contact metal 6 and the epitaxial layer at the lower trench sidewall.

The step of forming a second Schottky contact metal may include steps of depositing and patterning a metal layer to fill the trench and on top of the epitaxial layer, depositing and patterning a sacrificial layer on top of the metal layer, etching the metal layer and the sacrificial layer to expose a center portion of each mesa, and removing the sacrificial layer. It is noted that a Schottky junction can be formed between the second Schottky contact metal and the epitaxial layer at the upper trench sidewall. Also, the Schottky contact metal extends to the mesa with a predetermined length to form a Schottky junction at each corner of the mesas as well.

The step of forming a third Schottky contact metal may include the step of depositing a metal onto the center portion of each mesa and the second Schottky contact metal to form a Schottky junction between the Schottky contact metal and the epitaxial layer.

In the present invention, instead of PN junction, the trench sidewall of the Schottky diode is designed as Schottky junction to contribute to forward conduction, and the depth of the trench and the P-type implantation region are optimized to attain a better trade-off between the forward and reverse performance. In addition, multiple Schottky barrier layers are designed for the trench structure based on the electric field distribution, which can make a greater use of the trench structure to achieve a better trade-off between the forward voltage drop and the reverse leakage current performances.

### BRIEF DESCRIPTION OF THE DRAWINGS

FIG. 1 is a cross section view of the trench type junction barrier Schottky diode with multiple Schottky layers in the present invention.

FIGS. 2A to 2M are explanatory views for manufacturing processes of the trench type junction barrier Schottky diode.

FIG. 3 is a flow diagram illustrating a method for manufacturing the trench type junction barrier Schottky diode with multiple Schottky layers in the present invention.

FIG. 4 is a prior art showing a cross sectional structural view of a conventional trench type junction barrier Schottky diode.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

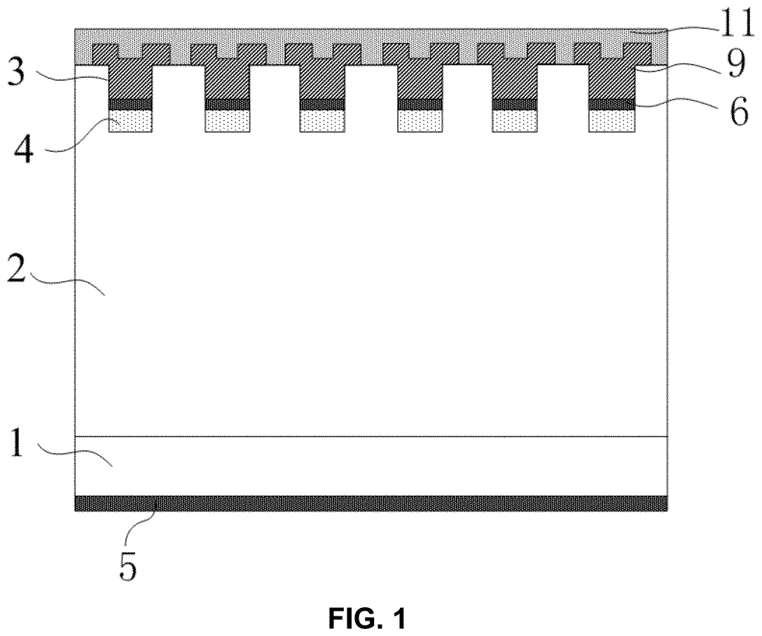

In one aspect, referring to FIG. 1, which illustrates a cross sectional view of a silicon carbide (SiC) multi-Schottky-layer trench junction barrier Schottky diode in the present invention, which may include a substrate 1, an epitaxial layer 2, a plurality of trenches 3, a P-type implantation region 4, an ohmic contact metal 5, a first Schottky contact metal 6, a second Schottky contact metal 9, and a third Schottky contact metal 11.

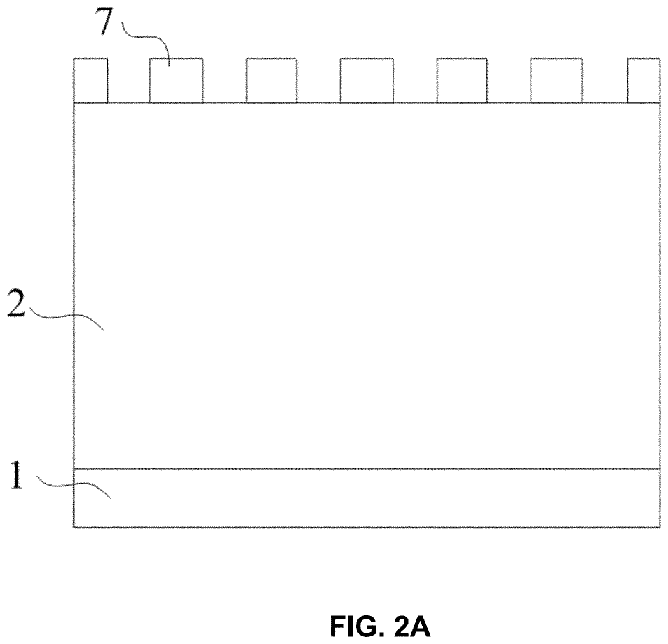

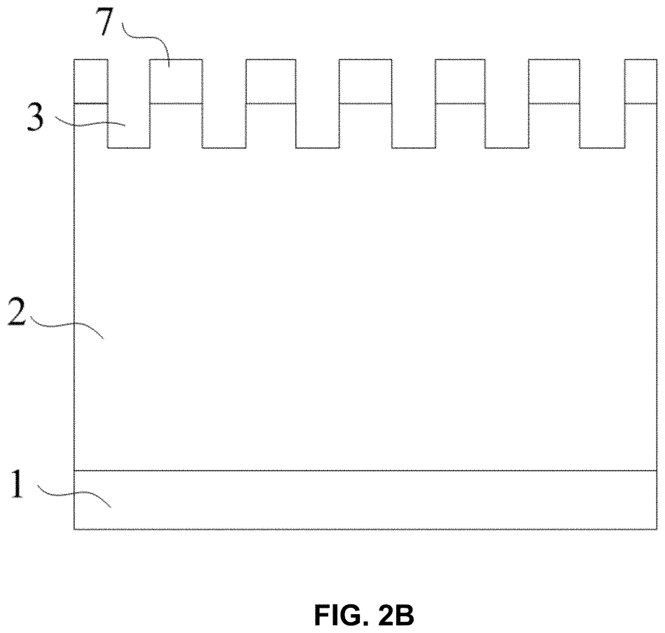

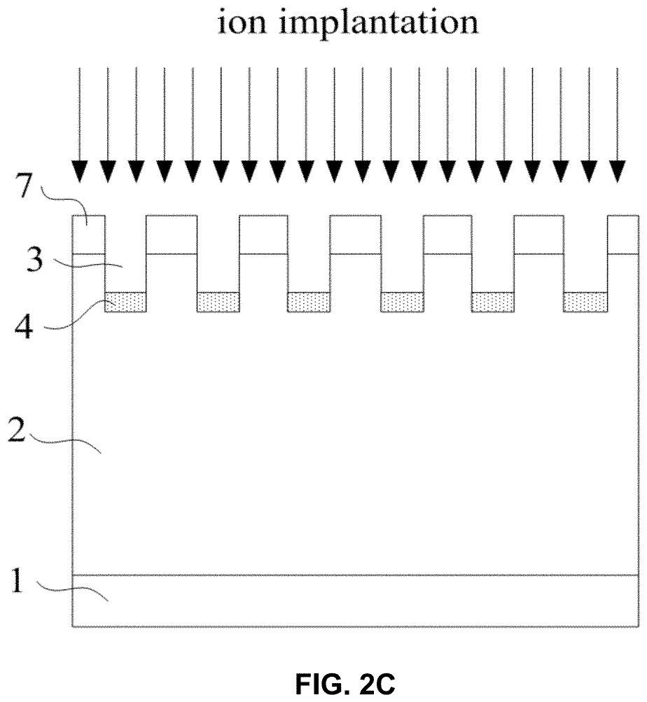

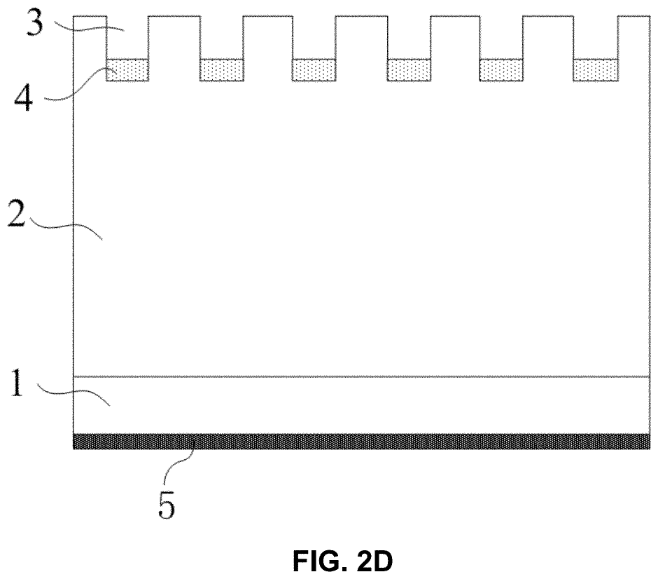

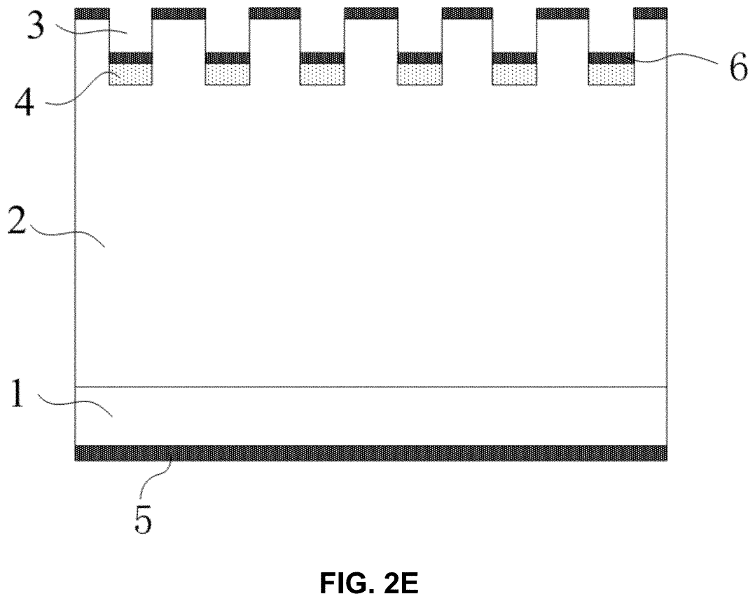

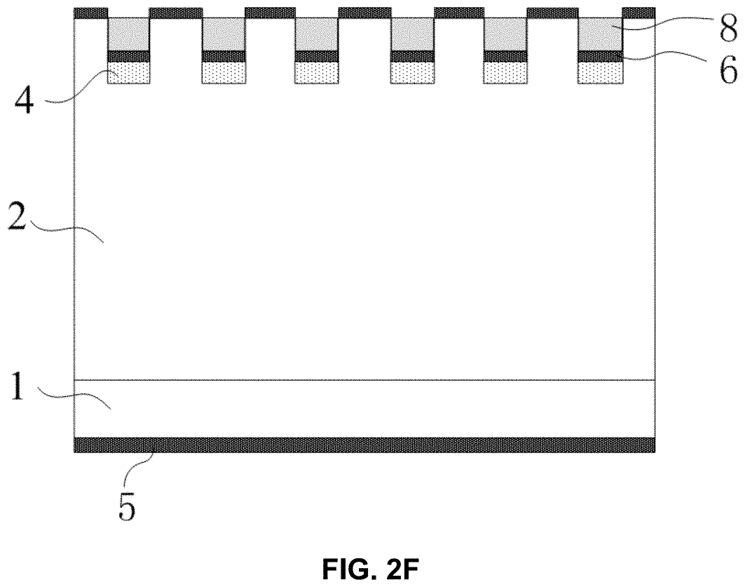

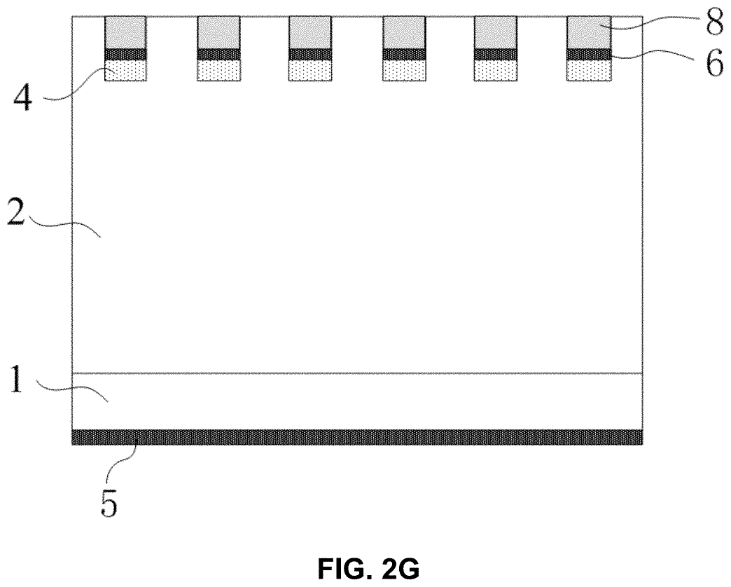

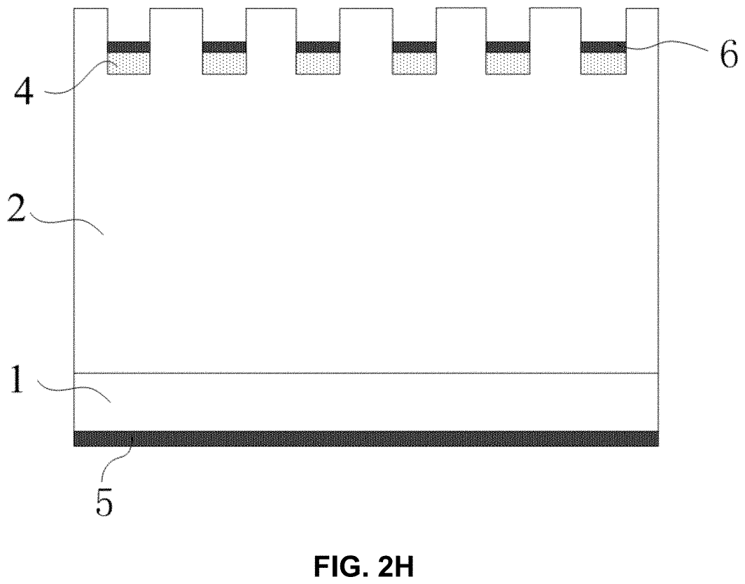

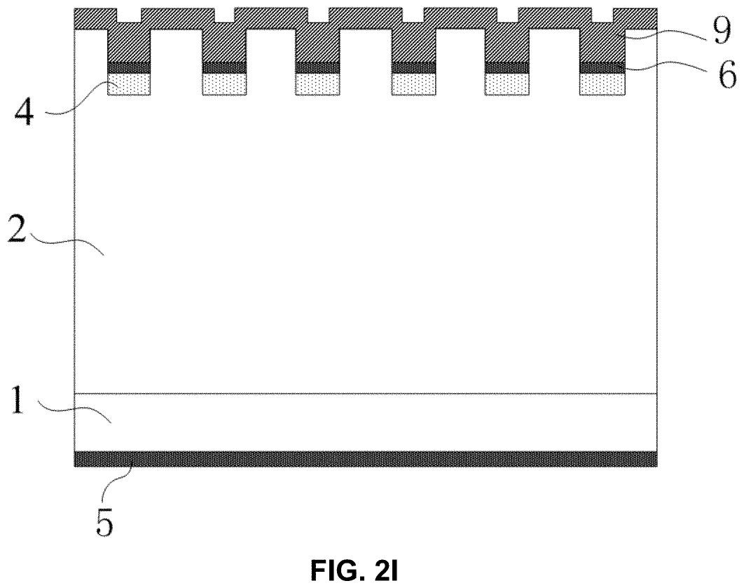

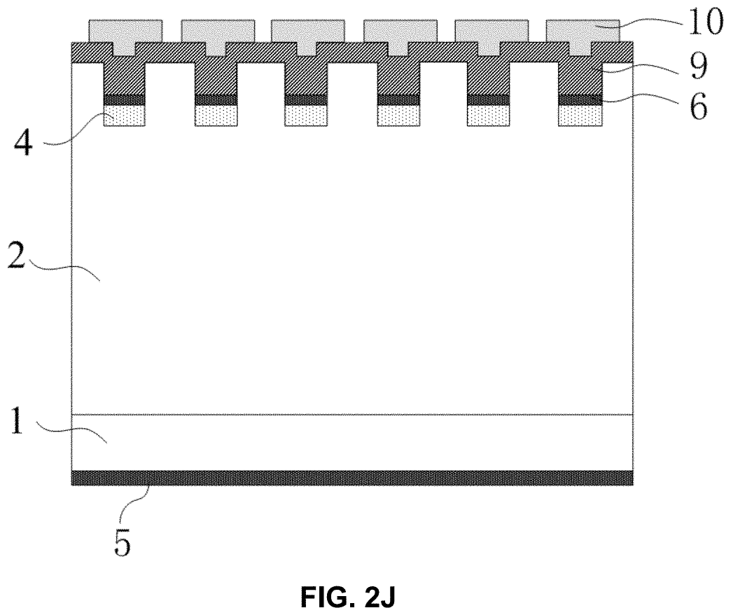

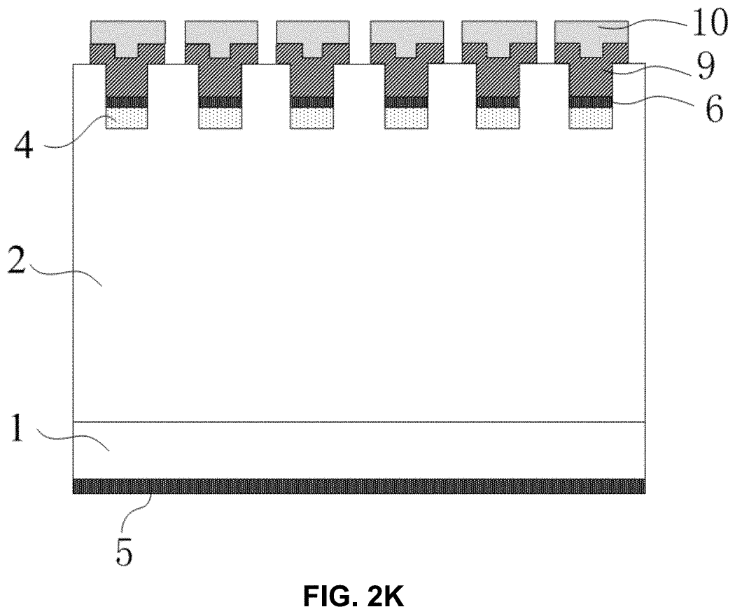

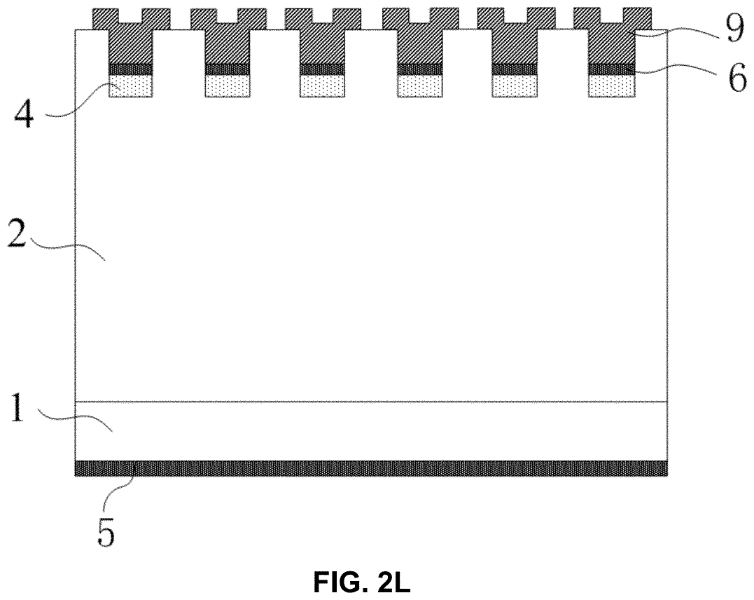

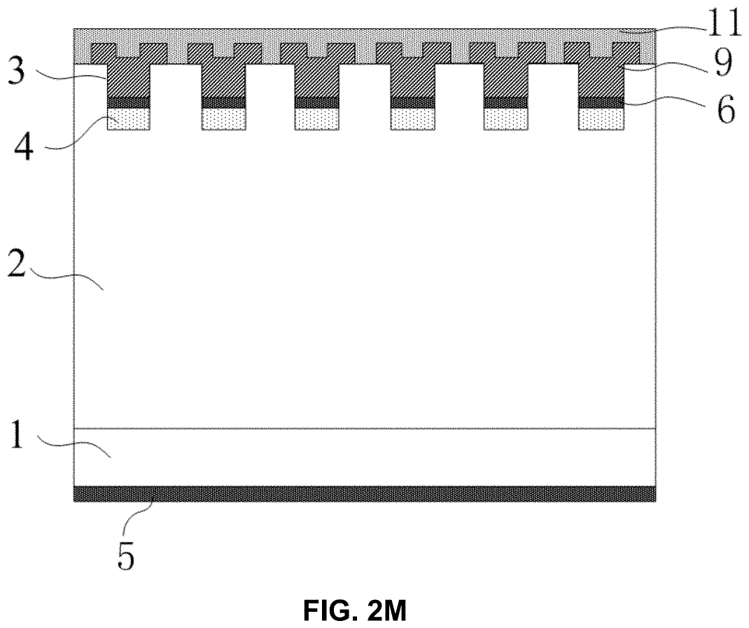

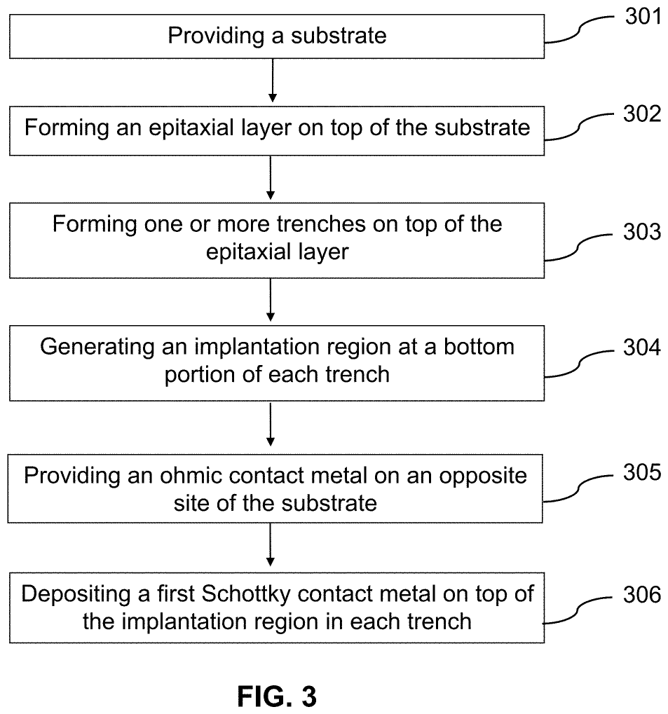

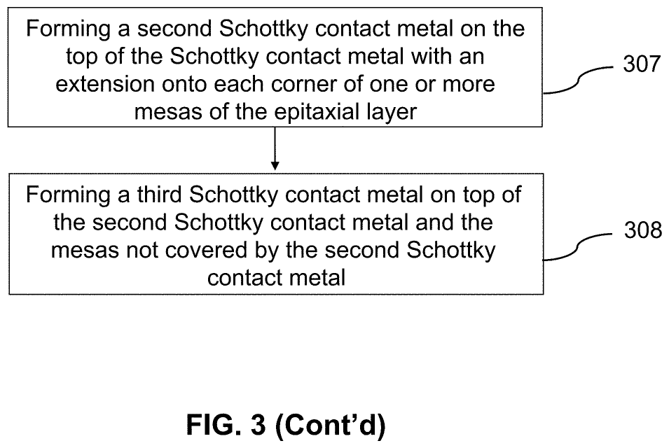

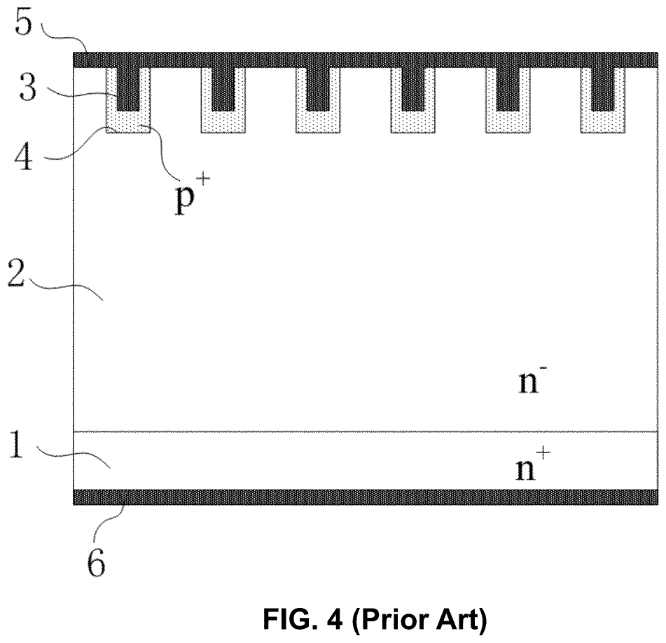

In one embodiment, the material selected for the ohmic contact metal 5 can be nickel, silver or platinum. The substrate 1 can be formed by N⁺ type SiC and is located on top of the ohmic contact metal 5 as shown in FIG. 2D. In another embodiment, the epitaxial layer 2 produced from N⁻ type SiC is located on top of the substrate 1, and the epitaxial layer 2 can further be patterned and etched with a mask layer 7 as shown in FIG. 2A to form the trenches 3. In one embodiment, the depth of each trench 3 is about 1 to 50000 angstrom. The P-type implantation region 4 can be generated at a bottom portion of each trench 3 by ion implantation as shown in FIG. 2C, and the P-type material may include boron or aluminum, for example. In one embodiment, the thickness of the P-type implantation region 4 is about 1 to 10000 angstrom.

In an exemplary embodiment, the first Schottky contact metal 6 is deposited on the P-type implantation region 4 in each trench 3 as shown in FIG. 2H, and a Schottky junction can be formed between the Schottky contact metal 6 and the epitaxial layer 2 at the lower trench sidewall. The second Schottky contact metal 9 is filled into each trench 3 and located on top of the first Schottky contact metal 6 as shown in FIG. 2L. A Schottky junction can be formed between the second Schottky contact metal 9 and the epitaxial layer 2 at an upper trench sidewall.

It is noted that the Schottky contact metal 9 extends to each corner of the mesas of the epitaxial layer 2 with a predetermined length. A Schottky junction can also be formed between the second Schottky contact meal 9 and the epitaxial layer 2 at each corner of the mesas.

In a further embodiment, the third Schottky contact metal 11 is deposited to cover the second Schottky contact metal 9 and the mesas that are not covered by the second Schottky contact metal 9. A Schottky junction can then be formed between the third Schottky contact metal 11 and the epitaxial layer 2 at a center portion of each mesa.

In another aspect, referring to FIG. 2A-2M, a method for manufacturing a silicon carbide (SiC) multi-Schottky-layer trench junction barrier Schottky diode may include steps of: step 301: providing a substrate 1; step 302: forming an epitaxial layer 2 on top of the substrate 1; step 303: forming one or more trenches 3 on the epitaxial layer 2; step 304: generating an implantation region 4 at a bottom portion of each trench 3; step 305: providing an ohmic contact metal 5 on an opposite of the substrate 1; step 306: depositing a first Schottky contact metal 6 on top of the implantation region 4 in each trench 3; step 307: forming a second Schottky contact metal 9 on the top of the Schottky contact metal 6 with an extension onto each corner of one or more mesas of the epitaxial layer 2; and step 308: forming a third Schottky contact metal 11 on top of the second Schottky contact metal 9 and the mesas not covered by the second Schottky contact metal 9.

In one embodiment, the step of providing the substrate 1 includes using N⁺ type SiC as a substrate, and the step of forming the epitaxial layer 2 may include forming an epitaxial layer made from N⁻ type SiC on top of the substrate 1. The step of forming one or more trenches 3 includes the step of patterning, etching and removing a portion of the epitaxial layer with a mask layer 7 to form the trenches as shown in FIGS. 2A and 2B. The step of forming the implantation region 4 may include the step of doping P-type impurity with the mask layer 7 into the bottom of the trench openings as shown in FIG. 2C.

In another embodiment, the step of providing an ohmic contact metal 5 includes the step of providing an ohmic contact metal underneath the substrate 1 as shown in FIG. 2D, and a Schottky junction can formed by depositing the first Schottky contact metal 6 on the implantation region 4 in each trench 3. As shown in 2E to 2H, the step of forming a first Schottky contact metal 6 may further include steps of depositing a metal layer on top of the epitaxial layer 2 and the implantation region 4 in each trench 3, forming a sacrificial layer 8 to fill each trench 3, removing the metal layer on the epitaxial layer 2, and removing the sacrificial layer 8 in each trench 3. It is noted that a Schottky junction between the first Schottky contact metal 6 and the epitaxial layer 2 at the lower trench sidewall.

As shown in FIGS. 21 to 2L, the step of forming a second Schottky contact metal 9 may include steps of depositing and patterning a metal layer 9 to fill the trench 3 and on top of the epitaxial layer 2, depositing and patterning a sacrificial layer 10 on top of the metal layer 9, etching the metal layer 9 and the sacrificial layer 10 to expose a center portion of each mesa, and removing the sacrificial layer. It is noted that a Schottky junction can be formed between the second Schottky contact metal 9 and the epitaxial layer 2 at the upper trench sidewall. Also, the Schottky contact metal 9 extends to the mesa with a predetermined length to form a Schottky junction at each corner of the mesas as well.

As shown in FIG. 2M, the step of forming a third Schottky contact metal 11 may include the step of depositing a metal onto the center portion of each mesa and the second Schottky contact metal 9 to form a Schottky junction between the Schottky contact metal 11 and the epitaxial layer 2.

In the present invention, instead of PN junction, the trench sidewall of the Schottky diode is designed as Schottky junction to contribute to forward conduction, and the depth of the trench and the P-type implantation region are optimized to attain a better trade-off between the forward and reverse performance. In addition, multiple Schottky barrier layers are designed for the trench structure based on the electric field distribution, which can make a greater use of the trench structure to achieve a better trade-off between the forward voltage drop and the reverse leakage current performances.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A Schottky diode comprising:
a substrate;
an epitaxial layer deposited on one side of the substrate;
one or more trenches formed on top of the epitaxial layer;
an implantation region at a bottom portion of each trench;
an ohmic contact metal deposited on the other side of the substrate;
a first Schottky contact metal deposited onto the implantation region in each trench;
a second Schottky contact metal filling each trench and extending a predetermined length to each corner of mesas on the epitaxial layer; and
a third Schottky contact metal covering the second Schottky contact metal and the epitaxial layer.

2. The Schottky diode of claim 1, wherein the substrate is made by N⁺ type silicon carbide (SiC) and the epitaxial layer is made by N⁻ type SiC.

3. The Schottky diode of claim 1, wherein a depth of each trench is about 1 to 50000 angstrom.

4. The Schottky diode of claim 1, wherein the P-type implantation region is generated by ion implantation.

5. The Schottky diode of claim 1, wherein a thickness of the P-type implantation region is about 1 to 10000 angstrom.

6. The Schottky diode of claim 1, wherein a first Schottky junction is formed between the first Schottky contact metal and the epitaxial layer at a lower trench sidewall.

7. The Schottky diode of claim 1, wherein a second Schottky junction is formed between the second Schottky contact metal and the epitaxial layer at an upper trench sidewall.

8. The Schottky diode of claim 1, wherein a third Schottky junction is formed between the third Schottky contact metal and a center portion of each mesa of the epitaxial layer.

9. A method for manufacturing a Schottky diode comprising steps of:
providing a substrate;
forming an epitaxial layer on top of the substrate;
forming one or more trenches on the epitaxial layer;
generating an implantation region at a bottom portion of each trench;
providing an ohmic contact metal on an opposite of the substrate;
depositing a first Schottky contact metal on top of the implantation region in each trench;
forming a second Schottky contact metal on the top of the Schottky contact metal with an extension onto each corner of one or more mesas of the epitaxial layer; and
forming a third Schottky contact metal on top of the second Schottky contact metal and the mesas not covered by the second Schottky contact metal.

10. The method for manufacturing a Schottky diode of claim 9, wherein the step of forming a first Schottky contact metal further includes steps of:
depositing a first metal layer on top of the epitaxial layer and the implantation region in each trench;
forming a first sacrificial layer to fill each trench;
removing the first metal layer on the epitaxial layer; and
removing the first sacrificial layer in each trench.

11. The method for manufacturing a Schottky diode of claim 9, wherein the step of forming a second Schottky contact metal 9 include steps of:
depositing and patterning a second metal layer to fill the trench and on top of the epitaxial layer;
depositing and patterning a second sacrificial layer on top of the metal layer;
etching the metal layer and the second sacrificial layer to expose a center portion of each mesa; and
removing the second sacrificial layer.

12. The method for manufacturing a Schottky diode of claim 9, wherein the step of forming a third Schottky contact metal further includes steps of depositing a metal onto a center portion of each mesa and the second Schottky contact metal.

13. The method for manufacturing a Schottky diode of claim 9, wherein the substrate is made by N⁺ type silicon carbide (SiC) and the epitaxial layer is made by N⁻ type SiC.

14. The method for manufacturing a Schottky diode of claim 9, wherein a depth of each trench is about 1 to 50000 angstrom.

15. The method for manufacturing a Schottky diode of claim 9, wherein a thickness of the P-type implantation region is about 1 to 10000 angstrom.

16. The method for manufacturing a Schottky diode of claim 9, wherein the step of forming one or more trenches includes the step of patterning, etching and removing a portion of the epitaxial layer with a mask layer to form the trenches.
